(19) United States
(12) Patent Application Publication
(10) Pub. No.: US 2009/0008133 A1
(43) Pub. Date: Jan. 8, 2009

(54) Patterned Circuits and Method for Making Same

(76) Inventors: Jeffrey W. Bullard, Gaithersburg, MD (US); Dennis M. Brunner, Columbia, MO (US); Paul M. Harvey, Austin, TX (US); Hideo Yamazaki, Austin, TX (US); Hiroki Satoh, Kanagawa (JP); Hisayuki Nagai, Kanagawa (JP)

Correspondence Address: 3M INNOVATIVE PROPERTIES COMPANY, PO BOX 33427, ST. PAUL, MN, 55133-3427, US

(21) Appl. No.: 11/568,028

(22) PCT Filed: Dec. 27, 2004
(86) PCT No.: PCT/US04/43606

§ 371 Date: Oct. 17, 2006

Related U.S. Application Data
(60) Provisional application No. 60/608,954, filed on Dec. 30, 2003.

(51) Int. Cl. H05K 1/03; H01R 43/00

(52) U.S. Cl. 174/255; 29/885

(57) ABSTRACT

Provided are patterned circuits with accurately aligned raised features. Also provided are methods for making the circuits using photoresist-on-photoresist patterning.

### TECHNICAL FIELD

The invention relates to patterned circuit features on a substrate and methods of making patterned circuits.

### BACKGROUND

An etched copper or printed polymer thick film circuit pattern over a polymer film base may be referred to as a flexible circuit or flexible printed wiring board. Flexible circuits generally include a pattern of conductive traces that are supported on a base substrate such as a layer of dielectric material. Originally designed to replace bulky wiring harnesses, flexible circuitry is often the only solution for the miniaturization and movement needed for current, cutting-edge electronic assemblies. Flexible circuits offer attributes such as fine pitch traces, complex circuit designs, and flexibility. Thin, lightweight and ideal for complicated devices, flexible circuit design solutions range from single-sided conductive paths to complex, multilayer three-dimensional packages. Electronic devices, medical devices, hard disk drive suspensions, ink jet printer pens, and touch or finger sensors are common applications for flexible circuits.

Multi-layered interconnect modules are widely used in the semiconductor industry to mechanically support integrated circuit chips and electrically attach the chips to printed wiring boards. Interconnect modules can be configured to support a single chip or multiple chips, and are typically identified by the designation SCM (single chip module) or MCM (multi-chip module).

An interconnect module provides interconnections that serve to electrically couple an integrated circuit chip to signal lines, power lines, and other components carried by a printed wiring board. In particular, the interconnect module provides interconnections that redistribute the densely packed inputs and outputs (I/Os) of the chip to corresponding I/Os on the printed wiring board. In addition to electrical interconnection, an interconnect module typically serves to mechanically couple a chip to a printed wiring board, and may perform other functions such as heat dissipation and environmental protection.

### SUMMARY

One aspect of the present invention features a process comprising: providing a substrate; preparing a first patterned layer of photoresist on said substrate; depositing conductive material in the pattern formed by the photoresist to a thickness less than the thickness of the photoresist layer; preparing a second patterned layer of photoresist at least partially overlapping said first patterned layer of photoresist such that at least a portion of the conductive material is exposed; depositing additional conductive material in said pattern formed by said first and second layers of photoresist such that the height of the thickest portion of conductive material does not exceed the height of the first layer of photoresist.

Another aspect of the present invention features a process comprising: providing a substrate; applying a layer of uncured photoresist to said substrate; curing a pattern into said photoresist except in at least one portion; removing said uncured photoresist from said at least one portion thereby forming at least one first cavity in said photoresist; depositing conductive material in said first cavity to a thickness less than the thickness of the photoresist layer; applying a second layer of uncured photoresist to said photoresist and conductive material layer; curing a pattern into said photoresist except in at least one second portion, said second portion at least partially overlapping said at least one first cavity; removing said uncured photoresist from said at least one second portion thereby forming at least one second cavity in said photoresist said second cavity at least partially overlapping said at least one first cavity; and depositing conductive material in said at least one second cavity to a desired thickness, wherein the height of the thickest portion of conductive material does not exceed the height of the first layer of photoresist material.

Another aspect of the present invention features a process comprising: providing a dielectric film having a first side and a second metal-coated side; applying a layer of uncured photoresist to said second metal-coated side of said dielectric film; curing a pattern into said photoresist except in at least one portion; removing said uncured photoresist from said at least one portion thereby forming at least one cavity in said photoresist; depositing metal in said first cavity to a thickness less than the thickness of the photoresist layer; applying a second layer of uncured photoresist to said photoresist and metal layer; curing a pattern into said photoresist except in at least one second portion, said second portion partially overlapping said at least one first cavity; removing said uncured photoresist from said at least one second portion thereby forming at least one second cavity in said photoresist, said second cavity at least partially overlapping said at least one first cavity; and depositing metal in said at least one second cavity to a desired thickness, wherein the total height of the thickest portion of the metal does not exceed the height of the first layer of photoresist.

Another aspect of the present invention features a process comprising: providing a substrate; applying a layer of uncured negative photoresist to said substrate; curing a pattern into said photoresist except in at least one portion; removing said uncured photoresist from said at least one portion thereby forming at least one cavity in said photoresist; depositing conductive material in said first cavity to a thickness less than the thickness of the photoresist layer; applying a layer of positive photoresist to said negative photoresist and conductive material layer; forming a pattern of exposed positive photoresist in at least one second portion, said second portion partially overlapping said at least one first cavity, said second cavity at least partially overlapping said at least one first cavity; removing said exposed positive photoresist from said at least one portion thereby forming at least one second cavity in said photoresist; and depositing conductive material in said at least one second cavity to a desired thickness, wherein the total thickness of the highest portion of the conductive material portion of the structure does not exceed the height of the first layer of photoresist material.

Another aspect of the present invention features an article comprising: a substrate; a conductive layer having a trace pattern; and a raised feature on a portion of the trace wherein the width of the raised feature is substantially the same as the width of the portion of the trace on which it is located.

Another aspect of the present invention features an article comprising: a substrate; a conductive layer having a trace pattern; and a raised feature on a portion of the trace, the raised feature comprising at least two layers of the same or different conductive material wherein the X and Y dimensions of the two layers are substantially the same and the two layers are substantially vertically aligned.

An advantage of at least one embodiment of the present invention is that it eliminates the need for precise flexible circuit-to-phototool alignment to when patterning circuit features.

Another advantage of at least one embodiment of the present invention is that it allows circuit feature formation on finer pitch traces.

Another advantage of at least one embodiment of the present invention is that raised circuit features only need to be aligned in a non-critical direction. This allows maximization of the feature widths in the bonding area.

An advantage of at least one embodiment of the present invention is that it can tolerate an image registration error greater than or equal to 50% of the character dimension of a circuit feature.

Other features and advantages of the invention will be apparent from the following drawings, detailed description, and claims.

### BRIEF DESCRIPTION OF DRAWINGS

FIGS. 1a to 1i depict steps of an embodiment of the method of the present invention.

FIGS. 2a to 2e depict steps of an embodiment of the method of the present invention.

FIG. 3 is a digital image of a flip-chip circuit made using a method of the present invention.

### DETAILED DESCRIPTION

Aspects of the present invention include additive methods for producing thickness-differentiated circuit features for electronic packaging and interconnect applications. The methods use an additive process that includes the buildup of two laminated photoresist layers in conjunction with two separate circuit plating steps. The process is particularly applicable to any circuit construction, including multi-metal layer packages and fine-pitch traces on flexible circuits, for which die-attach bumps or other raised features in a circuit are required in combination with high routing density. At least one embodiment of the invention provides excellent registration of the raised features with other circuit features.

A significant advantage of at least one embodiment of the present invention is that it does not require precise alignment between the substrate and phototool to image aligned circuit features on fine pitch traces. The methods of the present invention use a combination of photoresist-on-photoresist patterning and underfilling to achieve the desired multi-level structure. The negative photoresist type can be wet or dry type. The processes described herein use a negative dry type photoresist and a substrate with only one side having a conductive coating, but is easily extendable to two-metal layer circuits with the benefit of the teachings herein.

Conventional raised circuit feature formation processes form circuit traces on dielectric film with photolithography processes and etching, then forms the raised circuit feature on these traces using a second photolithography process which requires precise alignment between the already formed traces and images of desired circuit feature. This process is limited by the alignment tolerance, and cannot be applied to fine pitch circuit that exceed the alignment capability of the equipment. In addition to this limitation, the photoresist material does not always flow into fine openings in which circuit feature are supposed to be formed.

The manufacture of a number of electronic packaging constructions, including ball grid arrays, flip-chip architectures, and other integrated circuit package (ICP) constrictions, as well as for interconnection to display panels, printed wiring boards, or additional circuit layers require the ability to generate relatively thicker raised circuit features among other relatively thinner features such as wiring traces and via pads.

In a typical additive processing methodology, these raised features are generated by defining and electroplating a relatively large “capture pad” among the other thin circuit features, and then masking all features except the capture pad, upon which a relatively smaller raised contact pad is subsequently electroplated. The capture pad must be relatively large to accommodate registration errors that are incurred during the second expose and plating steps that defines the smaller contact pad. If one assumes a maximum registration error of 8 μm, then a circular capture pad would need to have a diameter D given by

d+2δ

where d is the diameter of the smaller raised contact pad feature, to ensure that the smaller feature would be positioned on the capture pad. The extra space required for the capture pad to account for registration error results in a loss of space in which circuit traces and other features could otherwise be placed.

In the ICP business climate, however, a premium is placed on greater routing densities. At least one aspect of the processing method of the present invention could provide a competitive market advantage possibility because it produces raised circuit features without the necessity of a large capture pad.

In one embodiment of the present invention, a dielectric substrate optionally may be coated with a seed layer of chrome, nickel or alloys thereof using a vacuum sputtering technique. Then a thin layer of nickel, copper, gold, platinum, palladium or alloys thereof is deposited using a vacuum sputtering technique to created a first conductive layer having a thickness of up to about 500 nm. This is followed by a subsequent plating of a conductive material such as tin, nickel, copper, gold, platinum, palladium or alloys thereof to increase the thickness of the first conductive layer to a total of between about 1 μm and about 5 μm thick. This process may be carried out on one or both sides of the dielectric substrate. As an alternative to these steps, a dielectric substrate having a layer of conductive material laminated to one or both surface may be used. A laminated conductive layer will typically have a thickness of about 1 to 5 μm. In either case, the dielectric substrate may be a polymer film such as polyester, polyimide, liquid crystal polymer, polyvinyl chloride, acryl are or polyolefin having a thickness of about 10 μm to about 600 μm. It should be noted that suitable thicknesses are not limited to these exemplary ranges.

A first negative photoresist layer is laminated on at least one side of the dielectric substrate having the conductive coating using standard dry or wet laminating techniques. For example hot roller lamination may be done using dry film, or moisture may be added to the integral surface prior to laminating the dry film. A suitable dry film is available as SF310 from MacDermid, Inc., Waterbury, Mass. The thickness of the photoresist is from about 1 μm to about 50 μm. The photoresist is then exposed to ultraviolet light or other suitable radiation, through a mask or phototool, which crosslinks the exposed portions of the resist. Suitable energy levels are about 50 mJ/cm² to about 500 mJ/cm² at a wavelength of about 365 nm. The mask is a negative image of the conductive layer features, e.g., traces. The unexposed portions of the photoresist are then developed with an appropriate solvent. For example, in the case of aqueous resists a dilute aqueous solution, e.g., a 0.5-1.5% sodium or potassium carbonate solution, is applied until the unexposed portion is removed and the desired patterns are obtained. The developing may be accomplished by immersing the substrate in the solution or spraying the solution on the substrate.

Another layer of conductive material is then plated on the exposed portion of the existing conductive layer using standard electroplating or electroless plating methods to a thickness less then the thickness of the photoresist. For example if a 40 μm thick dry film photoresist were used, the additional conductive layer would be plated to a thickness of about 15 μm to about 25 μm thick on top of the 1 to 5 μm first conductive layer.

A second photoresist layer is then laminated on at least one side of the metal-coated dielectric substrate using standard dry or wet laminating techniques. For example hot roller lamination may be done using dry film, or moisture may be added to the integral surface prior to laminating the dry film. The photoresist having sufficient flow characteristics to fill in the previously formed pattern. The photoresist is then exposed to ultraviolet light or other suitable radiation, through a mask or phototool, which crosslinks the exposed portions of the resist. Suitable energy levels are about 50 mJ/cm² to about 500 mJ/cm² at a wavelength of about 365 nm. The photoresist layer may be imaged such that only the locations of the raised features (e.g., die attach or interconnection bumps) will not be exposed to the UV light. The unexposed portions of the photoresist are then developed with an appropriate solvent. Typically, the openings in the second photoresist layer for the raised features will be larger than the openings formed in the first photoresist layer for the raised features. The larger opening in the second photoresist layer allows for more registration error in building the raised features. A positive resist may be used instead of a negative photoresist.

Alternatively, the second photoresist layer may be imaged such that a channel is formed in the second resist layer in the region where the raised features will be located. Removal of unexposed photoresist to form the channel will result in the formation of rectangular cavities on the portions of the traces where the raised features are desired. The raised features will be formed by plating up the conductive material in the rectangular cavities. This process requires even less stringent alignment than the alternative described in the previous paragraph because it requires precise alignment of the photoresist layers in only one direction rather than two directions in the plane of the material.

Another electroplating step is used to form the raised features with the maximum height of the raised feature not exceeding the height of the first photoresist layer. Suitable conductive materials for this step include tin, nickel, copper, gold, platinum, palladium or alloys thereof.

If desired, features may be etched in the dielectric film comprising the substrate by placing the circuit into a bath of concentrated base which etches the portions of the dielectric substrate not covered by crosslinked resist. The uncovered portions of the dielectric substrate may be non-metallized portions of the substrate exposed by openings in a photoresist layer or may be on a non-metallized side of the dielectric substrate. This etching step involves contacting unmasked areas of the polymeric film with a concentrated alkaline etching fluid. Useful alkaline etchants include aqueous solutions of alkali metal hydroxides and their mixtures with amines, as described in U.S. Pat. Nos. 5,227,008 and 6,403,211, for introducing holes and related voids into dielectric films. Time requirements for controlled thinning of dielectric film depend upon the type and thickness of the polymeric film. Film etching, using an alkaline etchant heated between 50° C. and 120° C. typically requires a time from about 10 seconds to about 20 minutes.

Typically, all of the photoresist is then stripped off the circuit in a 2-5% solution of an alkaline metal hydroxide at from about 20° C. to about 80° C., preferably from about 20° C. to about 60° C. Subsequently, the exposed portion of the first conductive layer is etched with an etchant such as the peroxide sulfuric etchant available under the trade name PERMA-ETCH from Electrochemicals Inc., Maple Plain, Minn.

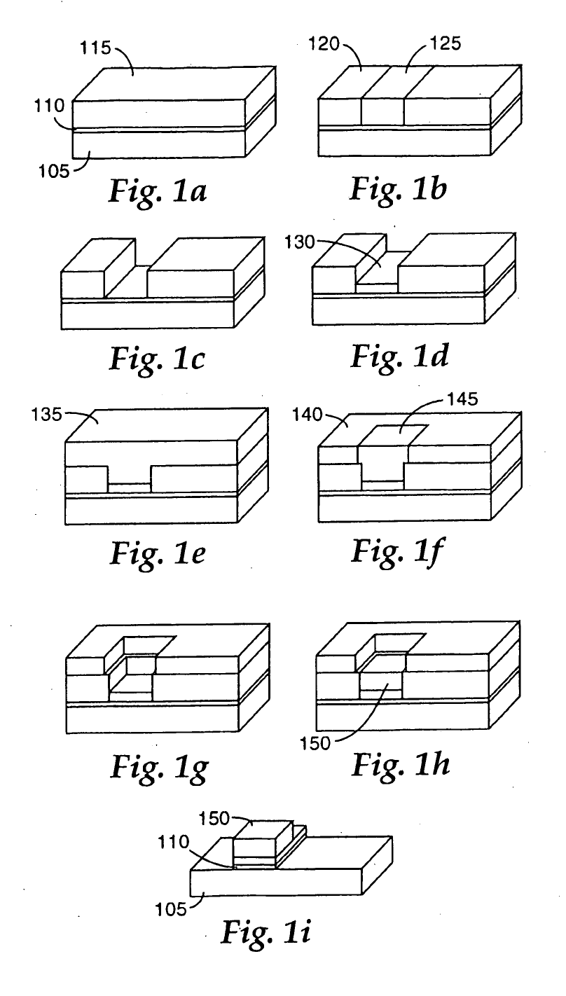

One embodiment of the present invention is illustrated by FIGS. 1a to 1i. FIG. 1a shows substrate 105 having a first conductive layer 110 and a thick laminate photoresist layer 115. FIG. 1b shows the structure after the photoresist layer has been exposed to a pattern of radiation to form a crosslinked portion 120 and uncrosslinked portion 125. FIG. 1c shows the structure after the uncrosslinked portion of the photoresist layer has been developed to form a patterned mask of the desired circuit trace pattern over the first conductive layer. FIG. 1d shows the structure with an electroplated second conductive layer 130 built up on the exposed first conductive layer using a continuous electrolytic plating method. The thickness of the electroplated layer is a fraction of the thickness of the photoresist layer, typically about 20% to about 75%. FIG. 1e shows the structure with a laminated second photoresist layer 135, FIG. 1f shows the structure after the second photoresist layer has been exposed to a pattern of radiation to form a crosslinked portion 140 and an uncrosslinked portion 145. FIG. 1g shows the structure after the uncrosslinked portion of the second photoresist layer has been developed to form a mask for the desired raised features, e.g., die-attach bumps, on the circuit pattern. The first and second patterned photoresist layers together form areas defining the desired raised features, which are accessible to the electrolytic plating solution. FIG. 1h shows the next step in which a second continuous electrolytic plating builds up the conductive material only in the areas on which the raised features are desired 150. The sum of the first and second continuous electrolytic plating thicknesses do not exceed the thickness of the first photoresist layer. This creates raised features having well-defined and symmetric shapes. The widths of the raised features are the same as the width of the circuit traces or other underlying circuit features (e.g., capture pads). FIG. 1i shows the structure after the photoresist layers have been removed and the exposed portion of the first conductive layer has been etched away. The resulting article is a multi-thickness circuit in which the raised features occupy the minimum possible amount of space to ensure their functionality. Because the methods of the present invention do not require precise alignment of the photoresist layers, they can tolerate an image registration error of 50% or more of the characteristic dimension of the circuit feature.

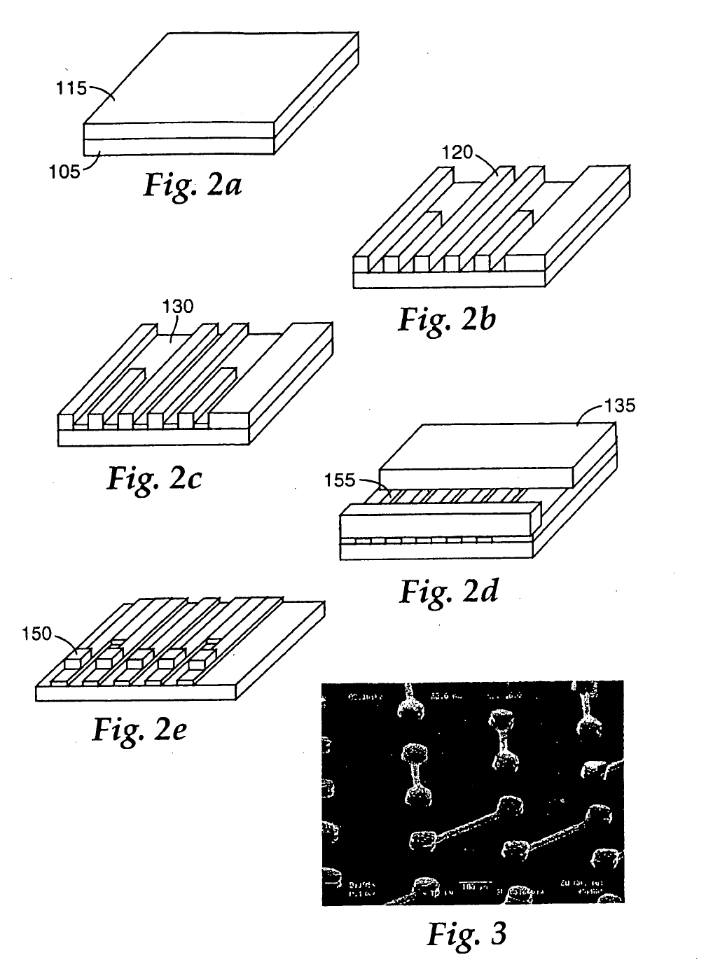

Another embodiment of the present invention is illustrated by FIGS. 2a to 2e. The main aspects of the process flow are illustrated in the figures. Peripheral process steps, such as flash plating, are not shown in the figures. In this embodiment, raised circuit features are formed by the following additive method. FIG. 2a illustrates an initial construction, which is made by coating a first photosensitive resist (photoresist) 115 on a dielectric substrate 105 (e.g., polyimide) having a first conductive layer (e.g., copper) (not shown) on the surface to be coated with photoresist. FIG. 2b illustrates that the first photoresist layer is then exposed to a pattern of radiation to form crosslinked portion 120 and the uncrosslinked portion of the photoresist is developed (i.e., removed) to create a desired circuit image or pattern. FIG. 2c shows the next step in which conductive material is electrolytically plated in the circuit pattern. The plated conductive material 130 is deposited on the portion of the first conductive layer exposed by the photoresist developing process. The second conductive layer thickness is less than the thickness of the first photoresist layer. FIG. 2d shows the next step in which, without removing the first photoresist layer after plating, a second photoresist layer is coated onto the structure, exposed to a pattern of radiation to form crosslinked, portion 140 and the uncrosslinked portion of the photoresist is developed to create a channel feature extending perpendicular to the longitudinal axis of the features of the circuit image (e.g., traces). To the extent conductive material was not plated up to the level of the first photoresist layer, the sidewalls of the first photoresist layer and the channel formed by the second photoresist create defined cavities 155. These cavities are positioned on a portion of the circuit features (e.g., traces). Additional plating is then performed to fill the cavities with conductive material up to the height of the first photoresist layer. After the second plating step has been performed, all of the photoresist is removed. The exposed portion of the first conductive layer is then etched away leaving isolated traces with raised features 150, as shown in FIG. 2e. The widths of the raised features are the same as the width of the circuit traces. Because of the accuracy provided by the invention, the raised features can be registered, with minimal error, to the surrounding circuit construction.

It should be noted that the defined openings in the photoresist layers are formed without precise alignment of the second photoresist layer to the first photoresist layer. With this method of the present invention, fine pitch features can be designed in an X direction, and coarse pitch features can be designed in a Y direction. The channel defined by the second developed photoresist layer does not require precise alignment to the circuit patterns in the first photoresist layer, which circuit patterns generally extend along the X direction. Precise alignment of the channel image in the Y direction is not needed because the channel image is of a coarse pitch.

Although the previous discussions generally describe the formation of raised features with linear dimensions, e.g., squares and rectangles, the methods of the present invention may also be used to form raised features with curved dimensions, e.g., circles and ovals. FIG. 3 shows an example of an actual flip-chip circuit with circular raised features that were made with a method of the present invention. To make the structure shown in FIG. 3, the first deposited and developed photoresist layer was patterned for traces terminated on each end with circular pads having diameters of about 100 μm. After conductive material was electroplated to partially fill the pattern, a second layer of photoresist was deposited and developed. The pattern of the second layer of photoresist comprised a series of circular openings having diameters of about 150 μm. The circular openings were positioned approximately over the circular pad features formed from the previous steps. Conductive material was again electroplated to build the height of the pad features to approximately the height of the first photoresist layer. The photoresist layers were then removed, leaving the traces with raised circular pad features. The raised pad features comprise two layers of deposited conductive material having substantially the same diameter and are substantially vertically aligned. With this embodiment of the method, the first photoresist layer established the diameter of the desired raised feature. The openings in the second photoresist layer need only overlap the circular features with enough precision to allow conductive material to be plated on the circular feature but not on a trace connected to a different pad.

### EXAMPLES

This invention may be illustrated by way of the following example.

To demonstrate this invention, an article with circuit and raised features was prepared. A 38 μm thick polyimide film with 3 μm copper on one side was used as a substrate. A 30 μm thick layer of photoresist was coated on the copper. A 50 μm trace pattern, was created by exposing portions of the photoresist to radiation (which caused it to crosslink) and developing the uncrosslinked portion of the photoresist. Next a 15 μm thick copper layer was plated on the portions of copper exposed between the remaining photoresist. Then a 30 μm thick second photoresist layer was coated on top of the structure. A 100 μm wide channel pattern was created in the second photoresist layer by exposing portions of the photoresist to radiation (which caused it to crosslink) and developing the uncrosslinked portion of the photoresist. Then a second 15 μm thick copper layer was plated on the portions of previously plated copper in the rectangular openings formed by the remaining portions of the first and second photoresist layers. The photoresist was removed to reveal traces having raised features in specific areas. Then 3 μm of copper was etched away to remove the original copper coating on the substrate, thereby isolating the traces.

Various modifications and alterations of this invention will become apparent to those skilled in the art without departing from the scope and spirit of this invention and it should be understood that this invention is not to be unduly limited to the illustrative embodiments set forth herein.

What is claimed is:

1. A process comprising:
providing a substrate;
preparing a first patterned layer of photoresist on said substrate;
depositing conductive material in the pattern formed by the photoresist to a thickness less than the thickness of the photoresist layer;
preparing a second patterned layer of photoresist at least partially overlapping said first patterned layer of photoresist such that at least a portion of the conductive material is exposed;
depositing additional conductive material in said pattern formed by said first and second layers of photoresist such that the height of the thickest portion of conductive material does not exceed the height of the first layer of photoresist.

2. The process of claim 1 further comprising removing at least a portion of said photoresist.

3. The process of claim 1 wherein the substrate comprises a metal-coated dielectric material.

4. The process of claim 3 wherein the metal-coating is less than 5 μm thick.

5. The process of claim 1 wherein the thickness of the first deposited conductive material is about 20% to about 75% of the thickness of first photoresist layer.

6. The process of claim 1 wherein the first photoresist layer is about 40 μm thick

7. The process of claim 6 wherein the first deposited conductive material is about 15 to about 25 μm thick

8. The process of claim 1 wherein the substrate is a dielectric material and a conductive material is deposited on said dielectric material prior to preparing said first patterned layer of photoresist.

9. The process of claim 8 wherein the conductive material on said dielectric material is deposited by sputtering.

10. The process of claim 8 wherein the conductive material on said dielectric material is deposited by lamination.

11. The process of claim 8 further comprising removing exposed portions of said conductive material on said dielectric material after photoresist covering the conductive material is removed.

12. A process comprising:
providing a substrate;
applying a layer of uncured photoresist to said substrate;
curing a pattern into said photoresist except in at least one portion;
removing said uncured photoresist from said at least one portion thereby forming at least one first cavity in said photoresist;
depositing conductive material in said first cavity to a thickness less than the thickness of the photoresist layer;
applying a second layer of uncured photoresist to said photoresist and conductive material layer;
curing a pattern into said photoresist except in at least one second portion, said second portion at least partially overlapping said at least one first cavity;
removing said uncured photoresist from said at least one second portion thereby forming at least one second cavity in said photoresist said second cavity at least partially overlapping said at least one first cavity; and
depositing conductive material in said at least one second cavity to a desired thickness, wherein the height of the thickest portion of conductive material does not exceed the height of the first layer of photoresist material.

13. A process comprising:
providing a dielectric film having a first side and a second metal-coated side;
applying a layer of uncured photoresist to said second metal-coated side of said dielectric film;
curing a pattern into said photoresist except in at least one portion;
removing said uncured photoresist from said at least one portion thereby forming at least one cavity in said photoresist;
depositing metal in said first cavity to a thickness less than the thickness of the photoresist layer;
applying a second layer of uncured photoresist to said photoresist and metal layer; curing a pattern into said photoresist except in at least one second portion, said second portion partially overlapping said at least one first cavity;
removing said uncured photoresist from said at least one second portion thereby forming at least one second cavity in said photoresist, said second cavity at least partially overlapping said at least one first cavity; and
depositing metal in said at least one second cavity to a desired thickness, wherein the total height of the thickest portion of the metal does not exceed the height of the first layer of photoresist.

14. The process of claim 13 further comprising:
removing at least a portion of the photoresist, and
removing said coated metal on said dielectric substrate in the portions that were covered by the removed photoresist.

15. A process comprising:
providing a substrate;
applying a layer of uncured negative photoresist to said substrate;
curing a pattern into said photoresist except in at least one portion;
removing said uncured photoresist from said at least one portion thereby forming at least one cavity in said photoresist;
depositing conductive material in said first cavity to a thickness less than the thickness of the photoresist layer;
applying a layer of positive photoresist to said negative photoresist and conductive material layer;
forming a pattern of exposed positive photoresist in at least one second portion, said second portion partially overlapping said at least one first cavity;
removing said exposed positive photoresist from said at least one portion thereby forming at least one second cavity in said photoresist, said second cavity at least partially overlapping said at least one first cavity; and
depositing conductive material in said at least one second cavity to a desired thickness, wherein the total thickness of the highest portion of the conductive material portion of the structure does not exceed the height of the first layer of photoresist material.

16. An article comprising:
a substrate;
a conductive layer having a trace pattern; and
a raised feature on a portion of the trace wherein the width of the raised feature is substantially the same as the width of the portion of the trace on which it is located.

17. The article of claim 16 wherein the raised feature has a squared shape.

18. An article comprising:
a substrate;
a conductive layer having a trace pattern; and
a raised feature on a portion of the trace, the raised feature comprising at least two layers of the same or different conductive material wherein the X and Y dimensions of the two layers are substantially the same and the two layers are substantially vertically aligned.

19. The article of claim 18 wherein the raised feature has a rounded shape.

20. The article of claim 19 wherein the raised feature is circular.
